(19) United States
(12) Patent Application Publication
(10) Pub. No.: US 2013/0196488 A1
(43) Pub. Date: Aug. 1, 2013

(54) Fin Structures with Damage-Free Sidewalls for Multi-Gate Mosfets

(71) Applicants: Bahman Hekmatshoartabari, White Plains, NY (US); Devendra K. Sadana, Pleasantville, NY (US); Ghavam G. Shahidi, Pound Ridge, NY (US); Davood Shahrjerdi, Ossining, NY (US)

(72) Inventors: Bahman Hekmatshoartabari, White Plains, NY (US); Devendra K. Sadana, Pleasantville, NY (US); Ghavam G. Shahidi, Pound Ridge, NY (US); Davood Shahrjerdi, Ossining, NY (US)

(73) Assignee: INTERNATIONAL BUSINESS MACHINES CORPORATION, Armonk, NY (US)

(21) Appl. No.: 13/605,085

(22) Filed: Sep. 6, 2012

Related U.S. Application Data
(63) Continuation of application No. 13/359,849, filed on Jan. 27, 2012.

(51) Int. Cl. H01L 21/20

(52) U.S. Cl. 438/481; 257/E21.131

(57) ABSTRACT

Improved Fin Field Effect Transistors (FinFET) are provided, as well as improved techniques for forming fins for a FinFET. A fin for a FinFET is formed by forming a semi-insulating layer on an insulator that gives a sufficiently large conduction band offset (ΔE_{c}) ranging from 0.05-0.6 eV; patterning an epitaxy mask on the semi-insulating layer, wherein the epitaxy mask has a reverse image of a desired pattern of the fin; performing a selective epitaxial growth within the epitaxy mask; and removing the epitaxy mask such that the fin remains on the semi-insulating layer. The semi-insulating layer comprises, for example, a III-V semiconductor material and optionally further comprises a Si δ-doping layer to supply electron carriers to the III-V channel.

### CROSS-REFERENCE TO RELATED APPLICATIONS

This application is a continuation of U.S. patent application Ser. No. 13/359,849, filed Jan. 27, 2012, incorporated by reference herein.

### FIELD OF THE INVENTION

The present invention relates generally to semiconductor devices, and, more particularly, to Fin Field Effect Transistors (FinFETs).

### BACKGROUND OF THE INVENTION

The downscaling of the physical dimensions of metal oxide semiconductor field effect transistors (MOSFETs) has led to performance improvements of integrated circuits and an increase in the number of transistors per chip. Multiple gate MOSFET structures, such as FinFETs and tri-gate structures, have been proposed as promising candidates for 14 nm technology nodes and beyond. In addition, high-mobility channel materials, such as III-Vs and Ge, have been proposed as technology boosters to further improve MOSFET scaling improvements.

For example, a FinFET is a multi-gate structure that includes a conducting channel formed in a vertical fin that forms the gate of the device. The thickness of the fin (measured from source to drain) determines the effective channel length of the device. Fins are typically formed in FinFETs by patterning the fin structures using direct etching of the layer of material that is to form the fin channel. The direct etching can cause damage to the fin sidewalls, where the carrier transport takes place, which can impair performance.

A number of techniques have been proposed or suggested for preventing or removing the damage to the fin sidewalls. For example, multiple oxidation and hydrogenation techniques have been employed to remove the fin sidewall damage. In addition, U.S. Pat. No. 6,835,628 to Dakshina-Murthy et al. discloses a method for forming a fin for a FinFET that employs a conductive seed layer. After the epitaxial growth of silicon and silicon germanium fins, the portions of the conductive seed layer that are not under the fins are removed, to electrically isolate the fins.

A need remains for improved methods for forming a fin of a FinFET that employ a semi-insulating layer that does not have to be removed. A further need remains for forming FinFETs having III-V and Ge fins without damaged sidewalls.

### SUMMARY OF THE INVENTION

Generally, improved Fin Field Effect Transistors (FinFET) are provided, as well as improved techniques for forming fins for a FinFET. According to one aspect of the invention, a fin for a FinFET is formed by forming a semi-insulating layer on an insulator that gives a sufficiently large conduction band offset (ΔE_{c}) ranging from 0.05-0.6 eV; patterning an epitaxy mask on the semi-insulating layer, wherein the epitaxy mask has a reverse image of a desired pattern of the fin; performing a selective epitaxial growth within the epitaxy mask; and removing the epitaxy mask such that the fin remains on the semi-insulating layer.

The semi-insulating layer comprises, for example, a III-V semiconductor material such as In₁₋ₓAlₓAs, Al₁₋ₓGaₓAs, In₁₋ₓ,GaₓP, In₁₋ₓGaₓAs, In₁₋ₓAlₓP, In_{1-x-y}AlₓGa_{y}As, or In_{1-x-y}AlₓGa_{y}P. The semi-insulating layer optionally further comprises a Si δ-doping layer to supply electron carriers to the III-V channel.

A more complete understanding of the present invention, as well as further features and advantages of the present invention, will be obtained by reference to the following detailed description and drawings.

### BRIEF DESCRIPTION OF THE DRAWINGS

FIGS. 1 and 2 illustrate a conventional process for forming fins on a FinFet device;

FIGS. 3 through 6 illustrate a process for forming fins on a FinFet device in accordance with the present invention; and

FIG. 7 illustrates the conduction band offset, ΔE_{c}, for the FinFet device of FIGS. 6A and 6B.

### DETAILED DESCRIPTION OF PREFERRED EMBODIMENTS

The present invention provides improved methods and apparatus for forming a fin of a FinFET that employ a semi-insulating layer that does not have to be removed. According to one aspect of the invention, FinFETs are formed having III-V and Ge fins without damaged sidewalls using selective epitaxial growth of semiconducting channel materials (for example, Ge, SiGe and III-V semiconductor materials) over an insulator (for example, SiO₂ or Si₃N₄).

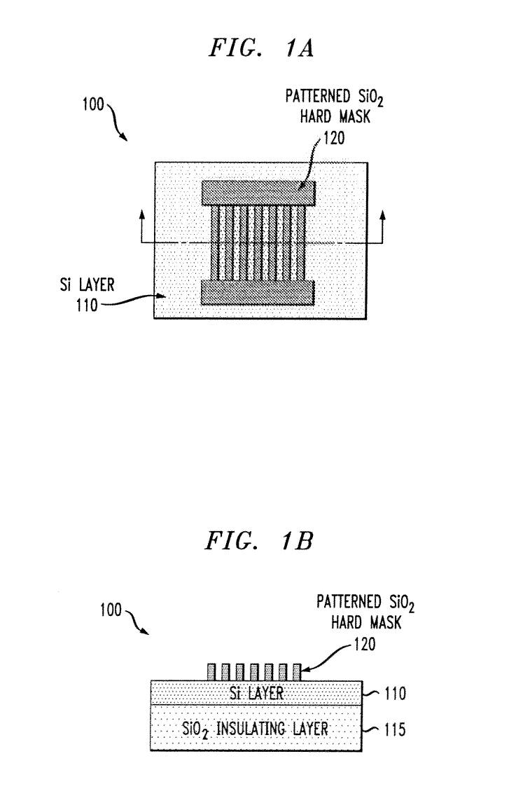

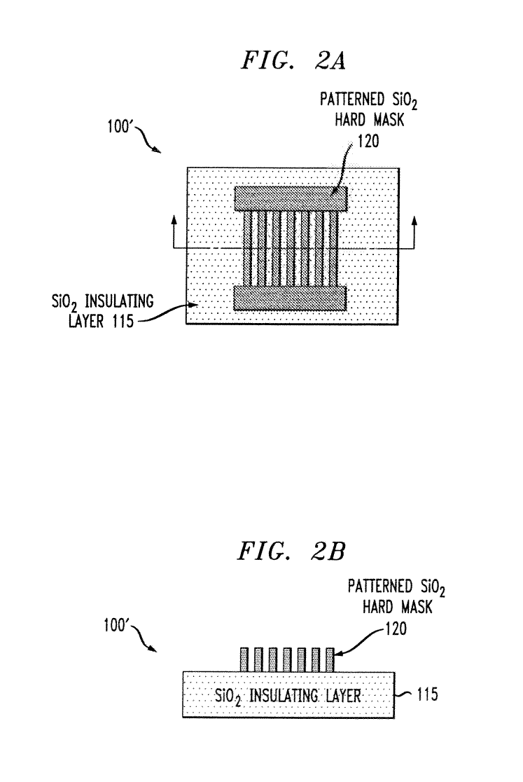

FIGS. 1 and 2 illustrate a conventional process for forming fins on a FinFet device 100. FIGS. 1A and 1B are top views and side views, respectively, of a portion of the conventional process for forming fins on a FinFet device 100. As shown in FIG. 1A, a silicon dioxide (SiO₂) hard mask 120 is applied on a layer 110 of silicon, for example, using lithography. As shown in FIG. 1B, the silicon layer 110 may be formed on a silicon dioxide (SiO₂) insulating layer 115.

FIGS. 2A and 2B are top views and side views, respectively, of a subsequent portion of a conventional process for forming fins on the FinFet device 100 of FIGS. 1A and 1B, following a dry etch step, such as a reactive ion etching (RIE). As shown in FIGS. 2A and 2B, the dry etch step removes the silicon layer 110 and the SiO₂ hard mask pattern 120 remains on the SiO₂ insulating layer 115. As indicated above, the dry etch process tends to damage the sidewalls of the fin structures, wherein the carrier transport takes place.

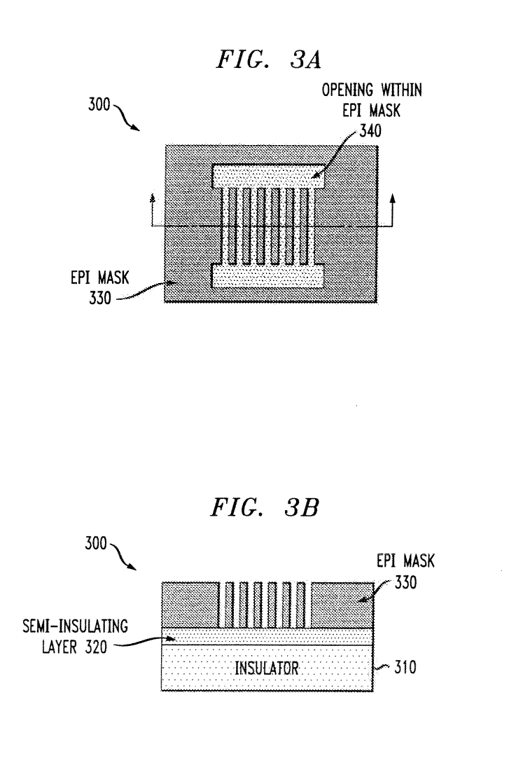

FIGS. 3 through 6 illustrate a process for forming fins on a FinFet device 300 in accordance with the present invention.

FIGS. 3A and 3B are top views and side views, respectively, of an Epi mask patterning portion of a process for forming fins on a FinFet device 300. As shown in FIG. 3B, a semi-insulating layer 320 is formed on an insulator 310, such as a semiconductor on insulator (SOI) substrate. The semi-insulating layer 320 can be comprised of a III-V semiconductor material, such as such as In₁₋ₓAlₓAs, Al₁₋ₓGaₓAs, In₁₋ₓGaₓP, In₁₋ₓGaₓAs, In₁₋ₓAlₓP, In_{1-x-y}AlₓGa_{y}As, or In_{1-x-y}AlₓGa_{y}P. The semi-insulatin layer 320 can be extremely thin or moderately thick, such as _{—}3-50 nm. It is noted that these III-V semiconductor materials can be used as a template for the growth of III-V fins, as well as a template for the growth of Ge fins, since some III-V semiconductor materials are lattice matched with III-V and Ge.

In one variation, shown in FIG. 3B, an optional Si delta-doping (δ-doping) material can be embedded in the semi-insulating layer 320. The optional embedded Si delta-doping (δ-doping) material can provide sufficient electron carriers into the channel to circumvent a low effective conduction band density of states.

In addition, as shown in FIG. 3A, an insulating epi mask 330 is deposited on the semi-insulating layer 320 using a lithography technique. The thickness of the deposited epi mask 330 should be equal to or thicker than the desired fin height. The epi mask 330 may comprise, for example, SiO₂ or Si₃N₄. The deposited epi mask 330 is then patterned to create the reverse image of the fins within the insulator. The epi mask 330 thus contains an opening 340 corresponding to the desired fin pattern.

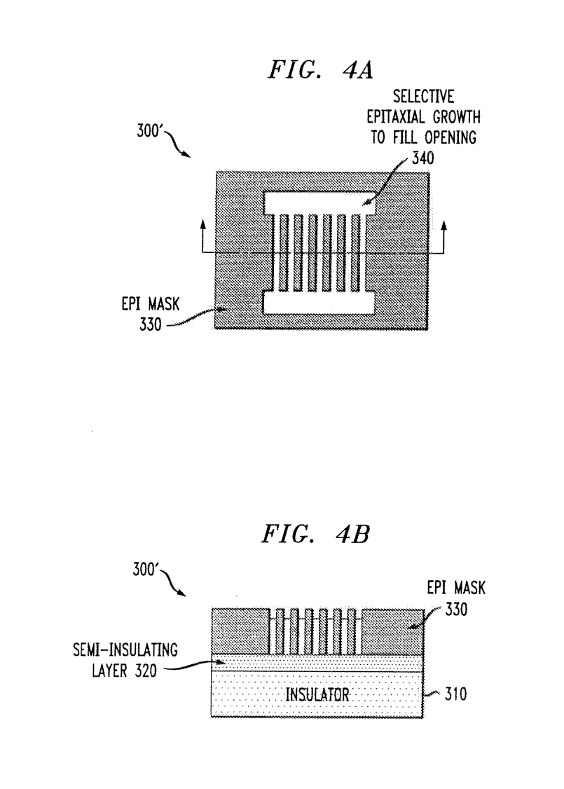

FIGS. 4A and 4B are top views and side views, respectively, of a selective epitaxial growth portion of a process for forming fins on a FinFet device 300′. As shown in FIG. 4A, selective epitaxial growth of the desired semiconductor channel material is performed to fill the opening 340 with the desired semiconductor channel material. The fin height is determined by the epitaxy process and the fin width is determined by the insulator opening 340.

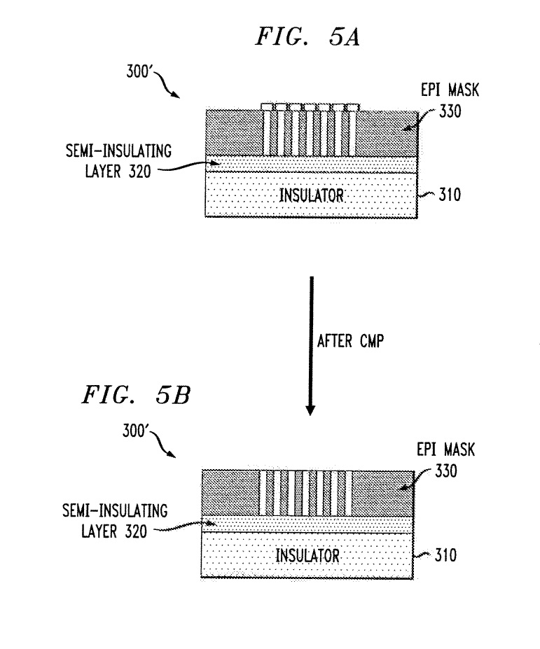

Alternatively, the thickness of the epitaxial III-V material may exceed that of the epi mask 330. Therefore, it may be necessary to employ chemical mechanical polishing (CMP) to flatten the top portion 510 of the fin while using the epi mask as an end point, as shown in FIGS. 5A and 5B. In this approach, the fin height is determined by the height of the epi mask 330.

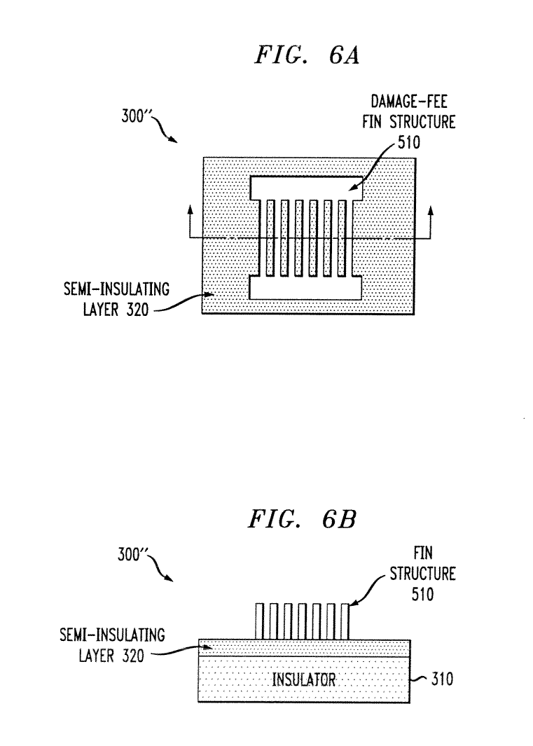

FIGS. 6A and 6B are top views and side views, respectively, of an epi mask removal portion of a process for forming fins on a FinFet device 300″. As shown in FIGS. 5A and 5B, the epi mask 330 is removed using a wet or dry etch process, such as a reactive ion etching (RIE), leaving a damage free fin channel structure 610. Thereafter, conventional techniques are performed to convert the fin structure 610 into transistors.

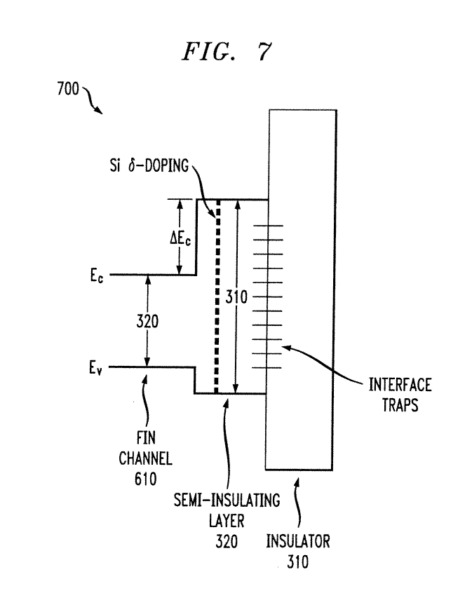

FIG. 7 illustrates the conduction band offset, ΔE_{c}, 700 for the FinFet device 300″ of FIGS. 6A and 6B. As indicated above, the conduction band 710 of the semi-insulating layer 320 should provide a sufficiently large conduction band offset with the conduction band 720 of the Fin channel structure 610.

It is noted that the conduction band (E_{c}) is the range of electron energies, higher than that of the valence band (Eᵥ), sufficient to free an electron from binding with its individual atom and allow it to move freely within the atomic lattice of the material. Electrons within the conduction band (E_{c}) are mobile charge carriers in solids, responsible for conduction of electric currents.

The foregoing description discloses only exemplary embodiments of the invention. Modifications of the above disclosed structures and method which fall within the scope of the invention will be readily apparent to those of ordinary skill in the art. Accordingly, while the present invention has been disclosed in connection with exemplary embodiments thereof, it should be understood that other embodiments may fall within the spirit and scope of the invention, as defined by the following claims.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

The corresponding structures, materials, acts, and equivalents of all means or step plus function elements in the claims below are intended to include any structure, material, or act for performing the function in combination with other claimed elements as specifically claimed. The description of the present invention has been presented for purposes of illustration and description, but is not intended to be exhaustive or limited to the invention in the form disclosed. Many modifications and variations will be apparent to those of ordinary skill in the art without departing from the scope and spirit of the invention. The embodiments were chosen and described in order to best explain the principles of the invention and the practical application, and to enable others of ordinary skill in the art to understand the invention for various embodiments with various modifications as are suited to the particular use contemplated.

What is claimed is:

1. A method for forming a fin for a Fin Field Effect Transistor (FinFET), comprising:
forming a semi-insulating layer on an insulator that gives a sufficiently large conduction band offset (ΔE_{c}) ranging from 0.05-0.6 eV;
patterning an epitaxy mask on said semi-insulating layer, wherein said epitaxy mask has a reverse image of a desired pattern of said fin;
performing a selective epitaxial growth within said epitaxy mask; and
removing said epitaxy mask such that said fin remains on said semi-insulating layer.

2. The method of claim 1, wherein said semi-insulating layer comprises a III-V semiconductor material.

3. The method of claim 2, wherein said semi-insulating layer comprises one or more of In₁₋ₓAlₓAs, Al₁₋ₓGaₓAs, In₁₋ₓGaₓP, In₁₋ₓGaₓAs, In₁₋ₓAlₓP, In_{1-x-y}AlₓGa_{y}As, and In_{1-x-y}AlₓGa_{y}P.

4. The method of claim 1, wherein said epitaxy mask comprises one or more of SiO₂ and Si₃N₄.

5. The method of claim 1. wherein said fin comprises one or more of Ge, SiGe and III-V semiconductor materials.

6. The method of claim 1, wherein said removing step further comprises an etching process.

7. The method of claim 1, wherein said semi-insulating layer further comprises a Si δ-doping layer to supply electron carriers to the III-V channel.
